(19) United States
(12) Patent Application Publication
(10) Pub. No.: US 2024/0170514 A1
(43) Pub. Date: May 23, 2024

(54) SOLID-STATE IMAGING ELEMENT AND ELECTRONIC APPARATUS

(71) Applicant: SONY SEMICONDUCTOR SOLUTIONS CORPORATION, KANAGAWA (JP)

(72) Inventor: HISASHI AKIYAMA, KANAGAWA (JP)

(21) Appl. No.: 18/548,882

(22) PCT Filed: Jan. 18, 2022
(86) PCT No.: PCT/JP2022/001489

§ 371 Date: Sep. 1, 2023

(30) Foreign Application Priority Data
Mar. 11, 2021 (JP) 2021-038963

(51) Int. Cl. H01L 27/146; G02B 5/20

(52) U.S. Cl. CPC H01L 27/1462; H01L 27/14618; H01L 27/14621; H01L 27/14627; H01L 27/14645; G02B 5/20

(57) ABSTRACT

The present disclosure relates to a solid-state imaging element and electronic apparatus that achieve image capturing with better image quality. A solid-state imaging element includes a semiconductor substrate in which a photoelectric conversion element is provided for each pixel, a filter layer stacked on a light-receiving surface side of the semiconductor substrate, and a plasmon filter disposed in the filter layer of at least some red pixels of a plurality of the red pixels that receives light in a red wavelength region, the plasmon filter including a plasmon resonator having a predetermined periodic pattern. Then, in the plasmon filter, a pitch of the pattern is corrected according to a position at which the red pixel is disposed. The present technology can be applied to, for example, an imaging element package.

### TECHNICAL FIELD

The present disclosure relates to a solid-state imaging element and an electronic apparatus, and especially relates to a solid-state imaging element and electronic apparatus that achieve image capturing with better image quality.

### BACKGROUND ART

Conventionally, when an image of a high-luminance subject such as the sun is captured by a solid-state imaging element, a phenomenon occurs in which a red dot appears around the high-luminance subject (hereinafter, referred to as a red-dot ghost phenomenon). Such a red-dot ghost phenomenon occurs due to light, which is reflected by an on-chip lens, a semiconductor substrate, or the like of the solid-state imaging element, being re-reflected by an infrared cut filter.

Therefore, Patent Document 1 discloses a solid-state imaging device that reduces occurrence of a ghost phenomenon or the like by providing a diffraction grating for reducing reflection. Furthermore, Patent Documents 2 and 3 disclose an imaging element including a filter utilizing plasmon resonance.

### CITATION LIST

### Patent Documents

Patent Document 1: Japanese Patent Application Laid-Open No. 2013-38164

Patent Document 2: Japanese Patent Application Laid-Open No. 2018-98341

Patent Document 3: Japanese Patent Application Laid-Open No. 2019-159080

### SUMMARY OF THE INVENTION

### Problems to be Solved by the Invention

However, reduction in reflection, as disclosed in Patent Document 1, cannot reliably eliminate occurrence of a red-dot ghost phenomenon, but can only reduce occurrence of a red-dot ghost phenomenon. Therefore, it is required to achieve image capturing with good image quality by reliably eliminating occurrence of a red-dot ghost phenomenon.

The present disclosure has been made to solve the above-mentioned problem and an object thereof is to achieve image capturing with better image quality.

### Solutions to Problems

A solid-state imaging element according to one aspect of the present disclosure includes a semiconductor substrate in which a photoelectric conversion element is provided for each pixel, a filter layer stacked on a light-receiving surface side of the semiconductor substrate, and a plasmon filter disposed in the filter layer of at least some red pixels of a plurality of the red pixels that receives light in a red wavelength region, the plasmon filter including a plasmon resonator having a predetermined periodic pattern.

An electronic apparatus according to one aspect of the present disclosure includes a solid-state imaging element including a semiconductor substrate in which a photoelectric conversion element is provided for each pixel, a filter layer stacked on a light-receiving surface side of the semiconductor substrate, and a plasmon filter disposed in the filter layer of at least some red pixels of a plurality of the red pixels that receives light in a red wavelength region, the plasmon filter including a plasmon resonator having a predetermined pattern.

In one aspect of the present disclosure, a photoelectric conversion element is provided for each pixel on a semiconductor substrate, a filter layer is stacked on a light-receiving surface side of the semiconductor substrate, and a plasmon filter disposed in the filter layer of at least some red pixels of a plurality of the red pixels that receives light in a red wavelength region includes a plasmon resonator having a predetermined periodic pattern.

### BRIEF DESCRIPTION OF DRAWINGS

FIG. 1 is a diagram illustrating a configuration example of a first embodiment of an imaging element package to which the present technology is applied.

FIG. 2 is a cross-sectional view illustrating a configuration example of a solid-state imaging element.

FIG. 3 is a diagram for describing excitation wavelengths of a plasmon filter.

FIG. 4 is a diagram for describing plasmon pupil correction.

FIG. 5 is a diagram for describing plasmon pupil correction.

FIG. 6 is a diagram illustrating an example of spectral response characteristics.

FIG. 7 is a diagram illustrating a configuration example of a second embodiment of an imaging element package to which the present technology is applied.

FIG. 8 is a diagram for describing relations between diffraction angles and effects of a plasmon filter.

FIG. 9 is a diagram illustrating a configuration example of a third embodiment of an imaging element package to which the present technology is applied.

FIG. 10 is a block diagram illustrating a configuration example of an imaging device.

FIG. 11 is a diagram illustrating a use example in which an image sensor is used.

### MODES FOR CARRYING OUT THE INVENTION

Hereinafter, specific embodiments to which the present technology is applied will be described in detail with reference to the drawings.

### First Configuration Example of Imaging Element Package

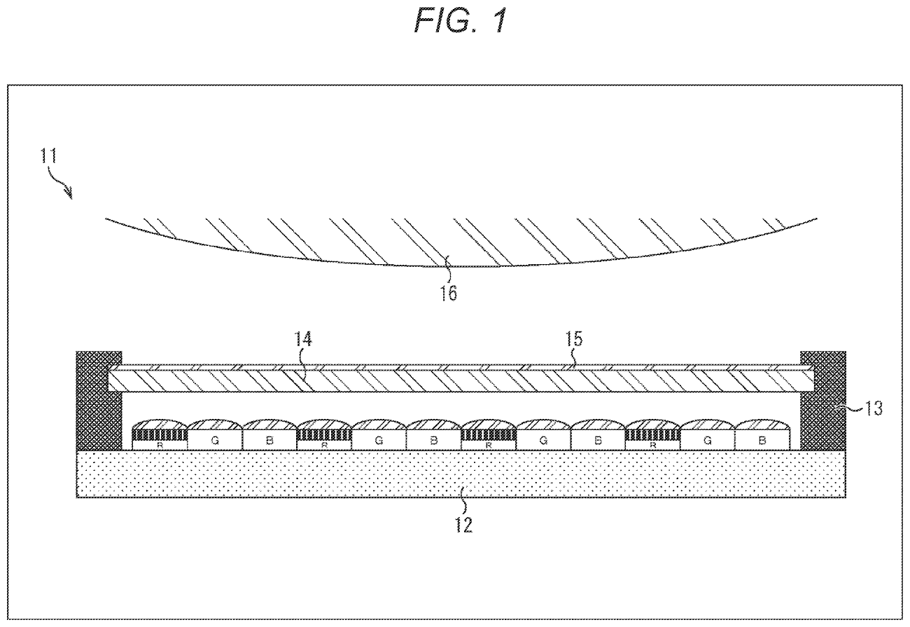

FIG. 1 is a diagram illustrating a configuration example of a first embodiment of an imaging element package including a solid-state imaging element to which the present technology is applied.

As illustrated in FIG. 1, an imaging element package 11 includes a solid-state imaging element 12, a holding member 13, a sealing glass 14, an infrared cut filter 15, and an imaging lens 16.

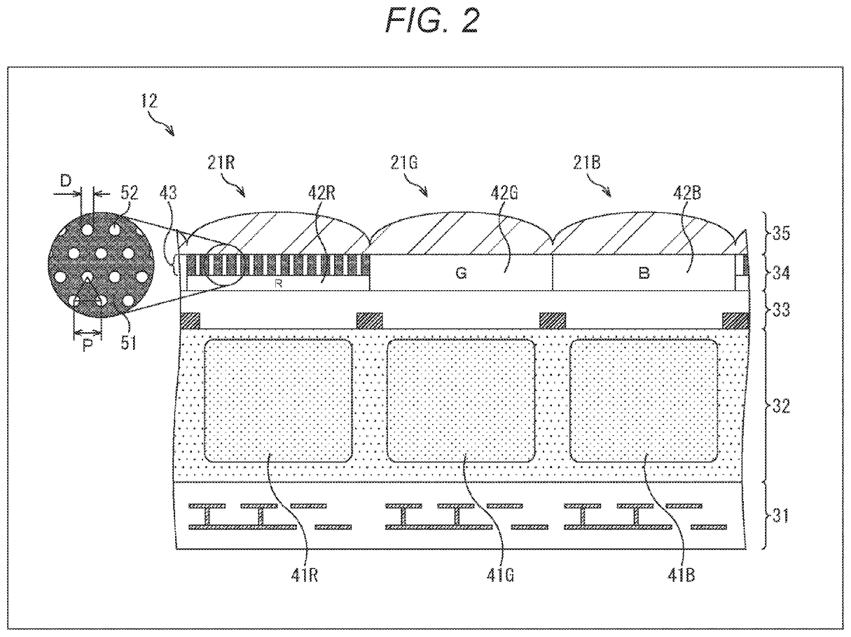

The solid-state imaging element 12 includes a plurality of pixels 21 (refer to FIG. 2 to be described later), each of which receives red, green, or blue light, the pixels 21 being arranged on a sensor surface, and an image is captured according to an amount of light received by the pixels 21.

The holding member 13 is a member for holding a periphery of the sealing glass 14 and fixing the sealing glass 14 to the solid-state imaging element 12.

The sealing glass 14 seals the sensor surface of the solid-state imaging element 12.

The infrared cut filter 15 is stacked on a surface of the sealing glass 14 to prevent light in the infrared wavelength range from being transmitted.

The imaging lens 16 condenses light from a subject (not illustrated) and forms an image on the sensor surface of the solid-state imaging element 12.

The imaging element package 11 is configured in this manner, and light for which infrared rays are cut off by the infrared cut filter 15 is incident on the solid-state imaging element 12, and an image can be captured.

FIG. 2 is a diagram illustrating a cross-sectional configuration example of the solid-state imaging element 12.

FIG. 2 illustrates a cross-sectional configuration of a pixel 21R that receives red light, a pixel 21G that receives green light, and a pixel 21B that receives blue light among the plurality of pixels 21 disposed on the sensor surface of the solid-state imaging element 12. As illustrated, the solid-state imaging element 12 includes a wiring layer 31, a semiconductor substrate 32, a flattening film 33, a filter layer 34, and an on-chip lens 35, which are stacked on top of each other.

The wiring layer 31 is provided with a wiring line for supplying a signal for driving a pixel 21, a wiring line for reading a pixel signal from a pixel 21, and the like.

A semiconductor substrate 32 is provided with photoelectric conversion units 41 for the respective pixels 21. A pixel signal is read from the semiconductor substrate 32, the pixel signal corresponding to a charge generated by light incident on the semiconductor substrate 32 being photoelectrically converted in a photoelectric conversion unit 41. As illustrated, the pixel 21R is provided with a photoelectric conversion unit 41R, the pixel 21G is provided with a photoelectric conversion unit 41G, and the pixel 21B is provided with a photoelectric conversion unit 41B.

The flattening film 33 is an insulation film formed to flatten a surface of the semiconductor substrate 32. For example, a light-shielding film that shields light between the pixels 21 is provided on the surface of the semiconductor substrate 32, and is flattened by forming the flattening film 33.

The filter layer 34 is stacked on the light-receiving surface side of the semiconductor substrate 32 via the flattening film 33, in which color filters 42 that transmit light of colors received by the respective pixels 21 are disposed. For example, a color filter 42G containing green dyestuff is disposed on the pixel 21G, and a color filter 42B containing blue dyestuff is disposed on the pixel 21B. Then, in the solid-state imaging element 12, for the pixel 21R, a two-layer structured filter is disposed in the filter layer 34, the filter including a color filter 42R containing red dyestuff and a plasmon filter 43 that transmits only light having a wavelength excited by plasmon resonance, which are stacked.

On the on-chip lenses 35, a microlens that condenses light is disposed for each pixel 21.

The plasmon filter 43 includes a plasmon resonator having a predetermined periodic pattern with a plurality of holes 52 formed in a metal film 51, and is disposed closer to a light-incident side (a side on which light is incident on the solid-state imaging element 12) than the color filter 42R is. For example, the plasmon filter 43 can be configured by forming, in a pattern in which a length of one side of a honeycomb-shaped regular triangle is an array pitch P, a plurality of holes 52 having a diameter D and in which a dielectric such as silicon dioxide is embedded, on the metal film 51 including a metal material such as aluminum. The plasmon filter 43 transmits only light having a wavelength excited by plasmon resonance corresponding to the array pitch P of the holes 52.

Note that, in the present embodiment, a plasmon resonator (hole-array structure) having a pattern in which the holes 52 are formed so as to penetrate the metal film 51 will be described. However, there can be applied to the plasmon filter 43 a plasmon resonator capable of obtaining a similar effect, such as a plasmon resonator having a pattern in which recesses not sufficiently deep to penetrating the metal film are formed in the metal film or a pattern in which a plurality of metal dots is disposed in a dielectric layer.

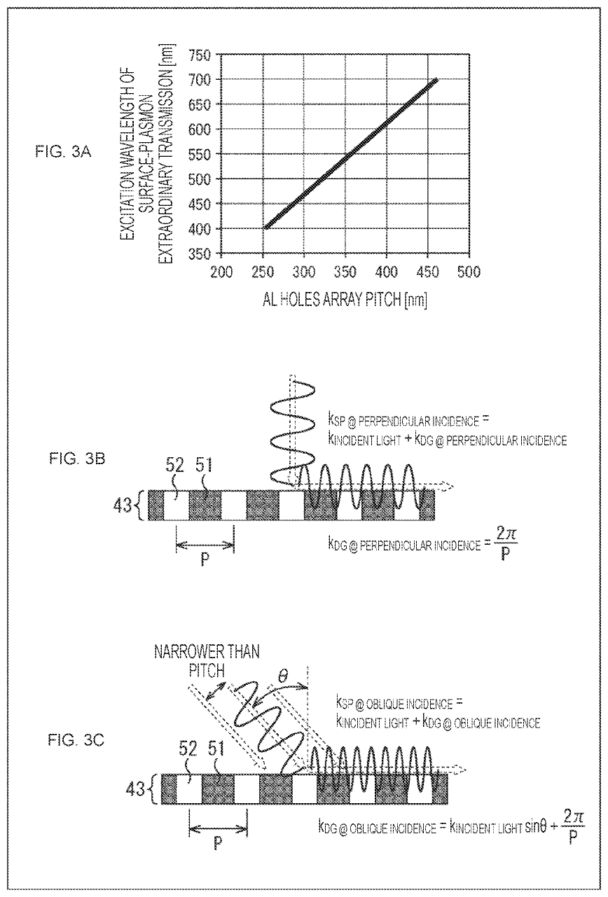

Excitation wavelengths of the plasmon filter 43 will be described with reference to FIG. 3.

A of FIG. 3 is a diagram illustrating a relation between the array pitch P of the holes 52 and an excitation wavelength of the plasmon filter 43 in which silicon dioxide is embedded in the holes 52 formed in the aluminum metal film 51. The horizontal axis indicates the array pitch P of the holes 52, and the vertical axis indicates the excitation wavelength of surface-plasmon extraordinary transmission obtained from a theoretical formula.

As illustrated, the excitation wavelength of the plasmon filter 43 is obtained according to the array pitch P of the holes 52.

B of FIG. 3 is a diagram illustrating a relation between a wave number k_{SP@perpendicular incidence} included in the surface plasmon and a wave number k_{DG@perpendicular incidence} of a diffraction grating pitch in a case where light is incident perpendicularly to the plasmon filter 43. C of FIG. 3 is a diagram illustrating a relation between a wave number k_{SP@oblique incidence} included in the surface plasmon and a wave number k_{DG@oblique incidence} of a diffraction grating pitch in a case where light is incident obliquely to the plasmon filter 43.

As illustrated in the drawings, a wavenumber shift is greater when light is obliquely incident on the plasmon filter 43 than when the light is perpendicularly incident on the plasmon filter 43, and therefore an excitation wavelength transmitted through the plasmon filter 43 is shifted to be a shorter wavelength. For example, light is perpendicularly incident on a central portion of the solid-state imaging element 12, whereas light is obliquely incident on a peripheral portion of the solid-state imaging element 12.

Therefore, in order to excite the same wavelength region on the central portion and peripheral portion of the solid-state imaging element 12, it is necessary to correct the array pitch P of the holes 52 provided in the plasmon filter 43 according a position at which the pixel 21R is disposed. For example, assuming that the array pitch P in a pixel 21R disposed on the central portion of the solid-state imaging element 12 is a reference pitch (the array pitch of the holes 52 for exciting red light), it is necessary to correct the array pitch P in the pixel 21R disposed on the peripheral portion of the solid-state imaging element 12 to be a corrected pitch wider than the reference pitch.

Here, in the present embodiment, correction of a configuration of the plasmon filter 43 of the pixel 21R so as to widen the array pitch P of the holes 52 from the central portion toward peripheral portion of the solid-state imaging element 12 is referred to as plasmon pupil correction.

In general, a pupil correction technique for image sensors is a technique in which structures (for example, an inter-pixel light shielding layer, an inner lens layer, a color filter layer, and an on-chip lens layer) in an upper layer of the image sensor is gradually shifted inward, toward edges of an angle of view. By applying such a pupil correction technique, response to light obliquely incident on the image sensor can be improved, and an oblique incidence characteristic (response uniformity) of an angle of view of the image sensor overall can be improved.

Then, similarly to the pupil correction technique, in a case of the surface plasmon, an extraordinary transmission phenomenon is induced by resonance of a single wavelength according to the array pitch P of the holes 52 formed in the metal film 51. Therefore, although influence of a decrease in response due to oblique incidence is infinitesimally small, an angle at which light is obliquely incident increases toward the edges of the angle of view, so that a resonance wavelength is shifted to be a shorter wavelength. For example, the plasmon filter 43 having an array pitch P of 350 nm resonates with light having a wavelength of 550 nm and incident on a central angle of view at 0 degrees. Meanwhile, the plasmon filter 43 having an array pitch P of 350 nm resonates with light having a wavelength of 450 nm and incident on an edge of an angle of view of a large-sized image sensor at an incidence angle of about 13 degrees.

Therefore, in the solid-state imaging element 12 to which the present technology is applied, by widening the array pitch P of the holes 52 at the edges of the angle of view of the large-sized image sensor to about 420 nm, a plasmon filter 43 at an edge of the angle of view can also resonate with light having a wavelength of 550 nm. That is, the solid-state imaging element 12 can improve oblique incidence characteristics (improve response at edges of angle of view) by performing plasmon pupil correction.

Specifically, an incidence angle from a lens on edges of an angle of view of an image sensor classified as a so-called large-sized sensor of an APS size (23.4 mm×16.7 mm) or a full size (24 mm×36 mm) is about 13 degrees. For example, assuming that light having a wavelength of 750 nm is incident at an angle of 0 degrees (direction perpendicular to an incident surface), an array pitch P resonating with the light is 460 nm. Because the array pitch P corresponds to 670 nm at edges of the angle of view at an angle of 13 degrees, oblique incidence characteristic can be improved by correcting the array pitch P at the edges of the angle of view to 670 nm.

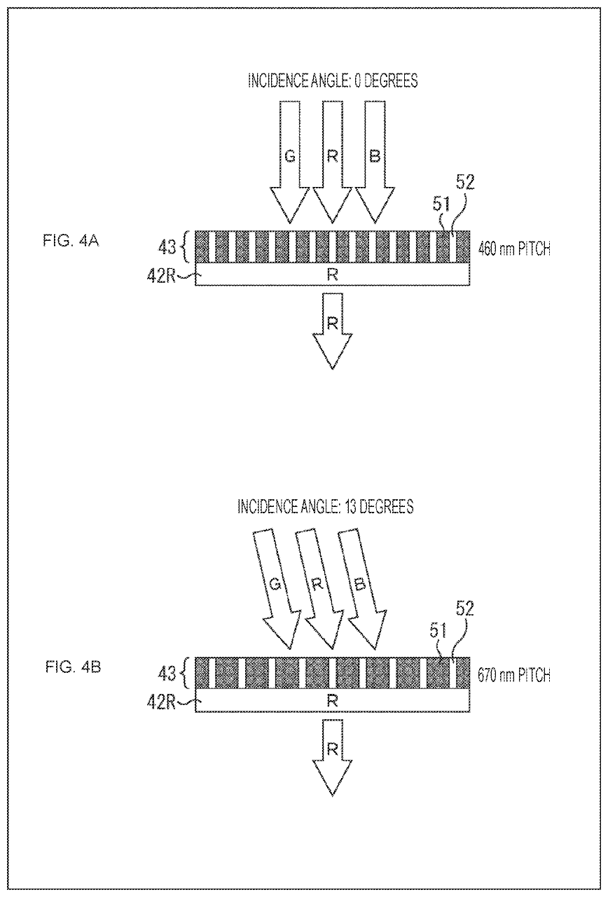

That is, A of FIG. 4 illustrates the plasmon filter 43 in which the array pitch P of the holes 52 disposed on the central portion of the solid-state imaging element 12 is 460 nm (reference pitch), and the plasmon filter 43 can excite and transmit only a red wavelength. Then, B of FIG. 4 illustrates the plasmon filter 43 in which the array pitch P of the holes 52 disposed in the peripheral portion of the solid-state imaging element 12 is 670 nm (corrected pitch), and only the red wavelength can be excited and transmitted by the plasmon pupil correction being performed corresponding to an incidence angle of 13 degrees on, for example, a horizontal edge of the angle of view. Therefore, the solid-state imaging element 12 can maintain response in both the central portion and the peripheral portion.

Incidentally, the wavelength of 750 nm incident on the solid-state imaging element 12 bounces off the on-chip lens, and the light of that wavelength is incident on the infrared cut filter 15 again at about 17 degrees according to the Bragg's diffraction formula. At this time, according to an angle response characteristic of the infrared cut filter 15, a wavelength in a red region, which is transmitted toward an upper layer of the infrared cut filter 15 in ordinary circumstances, is re-reflected due to a short wavelength shift of a cut region and is incident on the solid-state imaging element 12 again. A normal color filter as a red region transmits red light, thereby causing a red-dot ghost phenomenon. Meanwhile, because the plasmon filter 43 resonates only with light obliquely incident at 13 degrees, light incident at 17 degrees can be cut off.

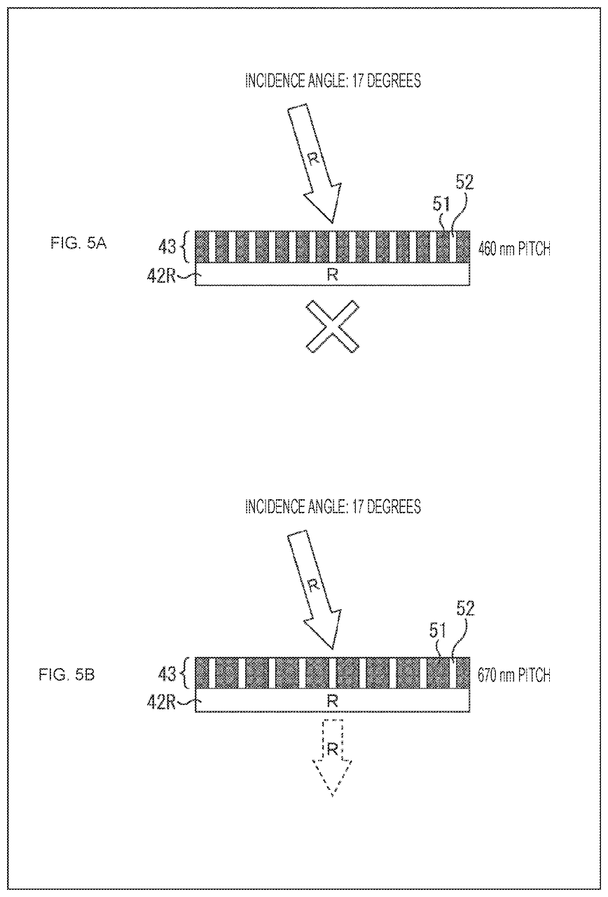

For example, as illustrated in A of FIG. 5, in the plasmon filter 43 in which the array pitch P of the holes 52 is 460 nm on the central portion of the solid-state imaging element 12, red light having an incidence angle of 17 degrees is not transmitted. Furthermore, as illustrated in B of FIG. 5, in the plasmon filter 43 in which the array pitch P of the holes 52 is 670 nm on the peripheral portion of the solid-state imaging element 12, an amount of red light having an incidence angle of 17 degrees can be reduced.

Therefore, because, in the solid-state imaging element 12, the pixels 21R can receive only light that can be transmitted through the plasmon filter 43, it is possible to reliably eliminate occurrence of a red-dot ghost phenomenon and flare phenomenon.

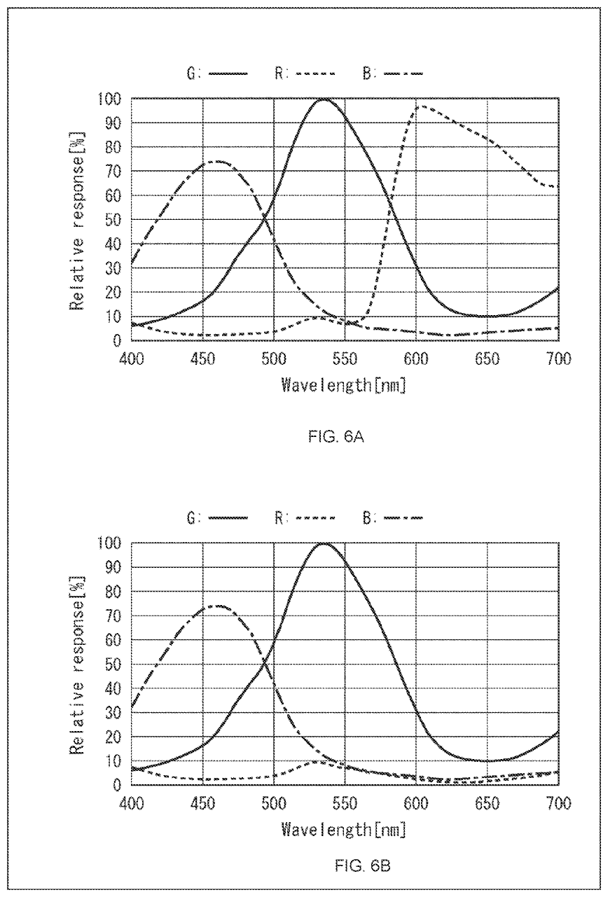

Images of effects in the solid-state imaging element 12 will be described with reference to FIG. 6.

A of FIG. 6 is a diagram illustrating response characteristics with respect to light incident on the solid-state imaging element 12 for each of a pixel 21R, pixel 21G, and pixel 21B. For example, in a conventional solid-state imaging element in which plasmon filters 43 are not disposed but only color filters 42R are disposed on the pixels 21R, light re-reflected by the infrared cut filter 15 has similar response characteristics.

B of FIG. 6 is a diagram illustrating response characteristics with respect to light re-reflected by the infrared cut filter 15 for each of a pixel 21R, pixel 21G, and pixel 21B. As illustrated, the solid-state imaging element 12 has a configuration in which the plasmon filters 43 are disposed on the pixels 21R, so that response of the pixels 21R to the re-reflected light can be greatly reduced. That is, in the solid-state imaging element 12, the light re-reflected by the infrared cut filter 15 is cut off by the plasmon filters 43.

As described above, by providing the plasmon filter 43 in the pixel 21R, the solid-state imaging element 12 can reliably eliminate occurrence of a red-dot ghost phenomenon, and capture an image with better image quality.

Note that the solid-state imaging element 12 may have a configuration in which the plasmon filter 43 is provided for all the pixels 21R disposed on the sensor surface, or a configuration in which the plasmon filter 43 is provided for at least some of the pixels 21R. Furthermore, the solid-state imaging element 12 is not limited to the two-layer structure of the color filter 42R and the plasmon filter 43, and can reliably eliminate occurrence of a red-dot ghost phenomenon even with a configuration in which, for example, only the plasmon filters 43 are provided in the filter layer 34 of the pixels 21R.

### Second Configuration Example of Imaging Element Package

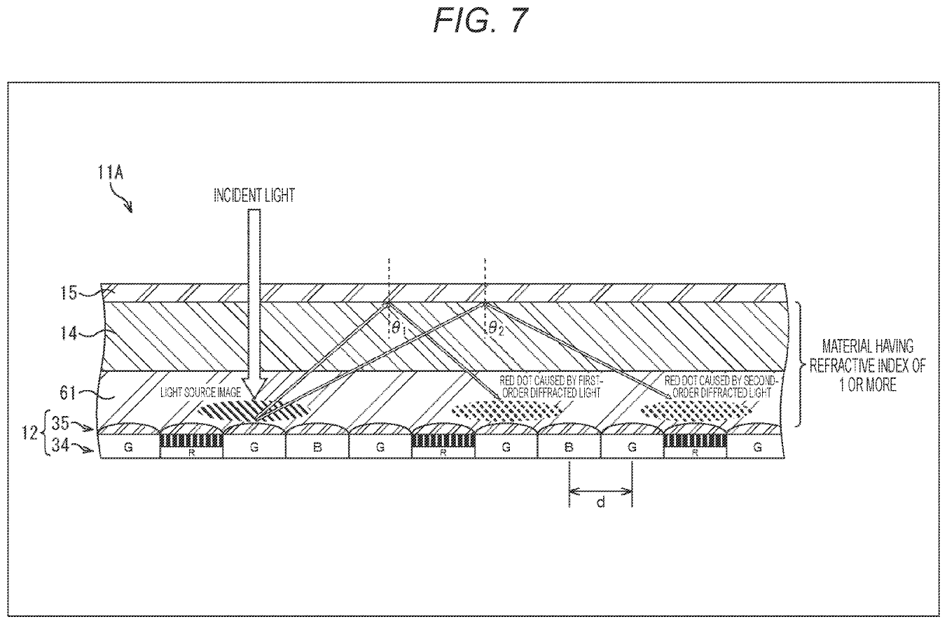

FIG. 7 is a diagram illustrating a configuration example of a second embodiment of an imaging element package including a solid-state imaging element to which the present technology is applied.

Similarly to the solid-state imaging element 12 illustrated in FIG. 2, an imaging element package 11A illustrated in FIG. 7 includes a filter layer 34 and on-chip lenses 35, which are stacked on the light-receiving surface side of the semiconductor substrate 32. Then, the imaging element package 11A has a configuration different from the configuration of the solid-state imaging element 12 in FIG. 2 in that a filling material 61 including a material having a refractive index of 1 or more is filled between on-chip lenses 35 and sealing glass 14. Furthermore, the sealing glass 14 also has a refractive index of 1 or more.

That is, the imaging element package 11A has a configuration in which a space between the on-chip lenses 35 and an infrared cut filter 15 is filled with a material having a refractive index of 1 or more. With the imaging element package 11A configured as described above, by further reducing a diffraction angle, red dots can be aggregated into a region where an image of a high-luminance subject such as the sun is captured. As a result, it is possible to avoid occurrence of a red-dot ghost phenomenon from being conspicuous. That is, an object of the imaging element package 11A is to make a high-luminance subject and a red dot indistinguishable from one another.

For example, silicon dioxide (SiO2) having a refractive index of about 1.5 can be used as the filling material 61, and the on-chip lenses 35 and the sealing glass 14 can be stacked so as to be filled with the material. In addition, for example, a gas such as air having a refractive index of 1 may be filled between the on-chip lenses 35 and the sealing glass 14.

Specifically, it is considered that, in a case where the imaging element package 11A has an APS size (Type 1.8=diagonal length 27 mm), a large amount of light is applied to an area of about 1/15 of the diagonal length in many cases, although it differs depending on an imaging situation. In such a case, it is considered that inclusion of up to a second-order diffracted light within an area having a diameter of 2.7 mm (that is, a radius is 1.35 mm) centered on a high-luminance subject makes it difficult to identify occurrence a red-dot ghost phenomenon.

For example, in a case where the diffraction angle is 10 degrees and an interval between the on-chip lenses 35 and the sealing glass 14 is 2 mm, the second-order diffracted light becomes a point of 1.4 mm from the center, and a diameter thereof exceeds 2.8 mm. At this time, in the imaging element package 11A in which the space between the on-chip lenses 35 and the sealing glass 14 is filled with a material having a refractive index of 1 or more, the second-order diffracted light becomes a point of 0.9 mm from the center, and the diameter thereof exceeds 1.8 mm, by which regions where red dots appear can be aggregated into an area of about 1/15 of the diagonal length (2.7 mm in diameter in length). As a result, the imaging element package 11A can achieve the object to make a high-luminance subject and a red dot indistinguishable from one another.

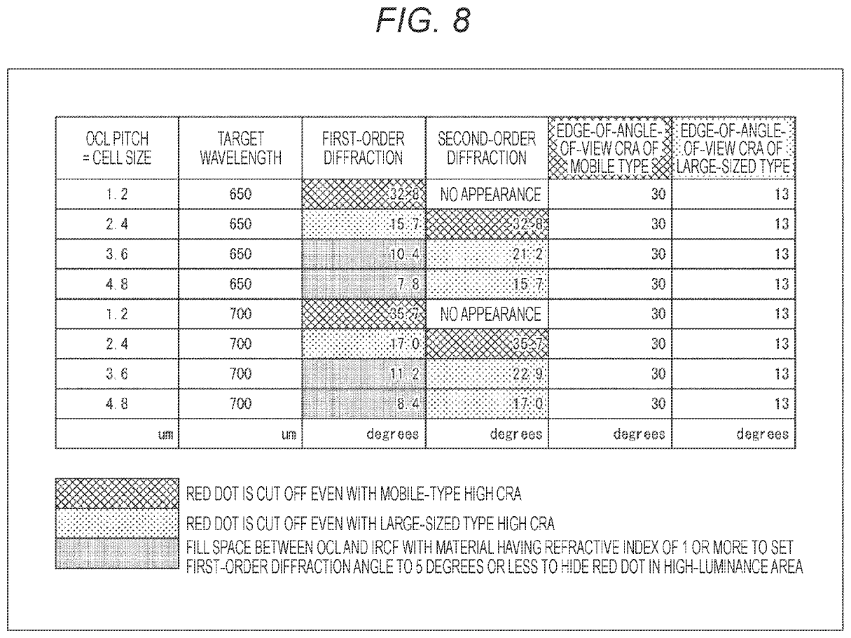

Here, with reference to FIG. 8, there will be described relations between edge-of-angle-of-views CRA (chief ray angle: light ray incidence angle) of the imaging element package 11 and effects of cutting off light (red dot), which is re-reflected by the infrared cut filter 15, by a plasmon filter 43 to reliably eliminate occurrence of a red-dot ghost phenomenon. In a case where the imaging element package 11 is of a mobile type, the edge-of-angle-of-view CRA is 30 degrees, and in a case where the imaging element package 11 is of a large-sized type, the edge-of-angle-of-view CRA is 13 degrees.

A diffraction angle θₘ in a diffraction order m is expressed by the following mathematical formula (1) using a size d of the pixel 21 (=a pitch of the on-chip lenses 35), a target wavelength λ, and a refractive index n.

$$\begin{matrix}[ Mathematical formula 1 ] & \\ d \times sin {θ}_{m} = \frac{m \times λ}{n} & ( 1 )\end{matrix}$$

FIG. 8 illustrates a first-order diffraction angle θ₁ and second-order diffraction angle θ₂ obtained in accordance with the mathematical formula (1) in cases where the size d of the pixel 21 is 1.2 μm, 2.4 μm, 3.6 μm, and 4.8 μm, and the target wavelength λ is 650 μm and 700 μm.

For example, in a case where the size d of the pixel 21 is 1.2 μm and the target wavelength λ is 650 μm, the first-order diffraction angle θ₁ is determined to be 32.8 degrees, which is equal to or larger than the edge-of-angle-of-view CRA of mobile type, whereby a red-dot ghost phenomenon can be cut off by plasmon filters 43 in the imaging element package 11 of mobile type. Of course, in this case, the first-order diffraction angle θ₁ is equal to or larger than the edge-of-angle-of-view CRA of large-sized type, whereby a red-dot ghost phenomenon can be cut off by plasmon filters 43 in the imaging element package 11 of large-sized type.

For example, in a case where the size d of the pixel 21 is 2.4 μm and the target wavelength λ is 650 μm, the first-order diffraction angle θ₁ is determined to be 15.7 degrees, and the second-order diffraction angle θ₂ is determined to be 32.8 degrees. Therefore, in the plasmon filters 43 in the imaging element package 11 of mobile type, a red-dot ghost phenomenon caused by first-order diffracted light can be cut off. Furthermore, in the plasmon filters 43 in the imaging element package 11 of large-sized type, a red-dot ghost phenomenon caused by first-order diffracted light and second-order diffracted light can be cut off.

Incidentally, the first-order diffraction angle θ₁ in cases where the size d of the pixel 21 is 3.6 μm and 4.8 μm is determined to be to be less than the edge-of-angle-of-view CRA of large-sized type. As described above, in a case where the diffraction angle is narrow and the plasmon filters 43 cannot cut off a red-dot ghost phenomenon caused by first-order diffracted light, it is preferable to further narrow the diffraction angle (to 5 degrees or less, for example) by filling a space between the on-chip lenses 35 and the infrared cut filter 15 with a material having a refractive index of 1 or more, as in the imaging element package 11A. With this arrangement, by further reducing a diffraction angle, red dots can be aggregated into a region where an image of a high-luminance subject such as the sun is captured. As a result, it is possible to avoid occurrence of a red-dot ghost phenomenon from being conspicuous.

### Third Configuration Example of Imaging Element Package

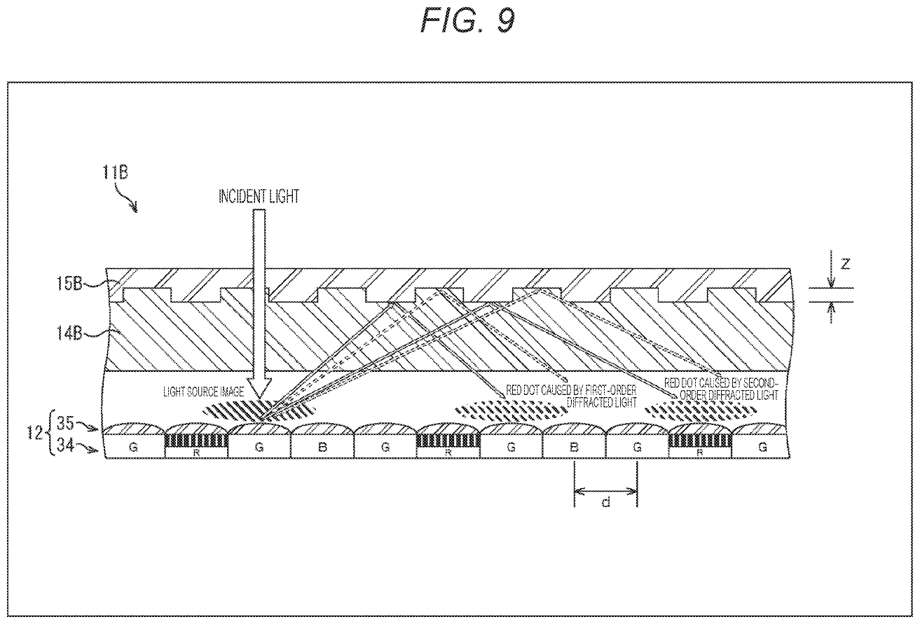

FIG. 9 is a diagram illustrating a configuration example of a third embodiment of an imaging element package including a solid-state imaging element to which the present technology is applied.

An imaging element package 11B illustrated in FIG. 9 has configuration different from the configuration of the imaging element package 11 in FIG. 1 in that an uneven surface in which recesses and projections are repeatedly arranged is provided on a boundary surface between a sealing glass 14B and an infrared cut filter 15B.

For example, a pitch in a surface direction of the uneven surface at the boundary surface between the sealing glass 14B and the infrared cut filter 15B is preferably about one to two times a size d of a pixel 21, which is a cell pitch.

Furthermore, a step Z in a thickness direction of the uneven surface at the boundary surface between the sealing glass 14B and the infrared cut filter 15B is formed to be ¼ of a red wavelength. Therefore, by light traveling back and forth between the step Z in the thickness direction of the uneven surface, an optical path difference between the recesses and projections is twice the step Z, whereby phases are inverted between light reflected on the projections (solid arrows in FIG. 9) and light reflected on the recesses (dashed arrows in FIG. 9). With this arrangement, it is possible to obtain an effect of offsetting amplification intensity when the reflected light is incident on a solid-state imaging element 12, and therefore to reduce chances of photoelectric conversion of the reflected light. As a result, it is possible to prevent occurrence of a red-dot ghost phenomenon caused by reflected light.

Here, a red wavelength defining the step Z in the thickness direction of the uneven surface is optimally about 650 nm to 700 nm, in consideration that a wavelength at just around a middle of a wavelength region where light is cut off by the infrared cut filter 15B has a highest offset effect. Furthermore, the pitch in the surface direction of the uneven surface is optimally about twice the cell pitch, in consideration that the offset effect is weakened if the pitch is too long.

Specifically, in a case where the size d of the pixels 21 is 2.4 μm, it is preferable to form the uneven surface on the boundary surface between the sealing glass 14B and the infrared cut filter 15B so that the pitch in the surface direction of the uneven surface is 4.8 μm (=2×2.4 μm), and the step Z in the thickness direction of the uneven surface is 175 nm (=700 nm×¼). It is a sufficiently feasible range as a process technique for performing such a process.

The imaging element package 11B configured as described above can improve an effect of reducing occurrence of a red-dot ghost phenomenon, by providing the uneven surface on the boundary surface between the sealing glass 14B and the infrared cut filter 15B.

### Configuration Example of Electronic Apparatus

The above-described solid-state imaging element 12 is applicable to, for example, various electronic apparatuses including an imaging system such as a digital still camera and a digital video camera, a mobile phone having an imaging function, and another device having an imaging function.

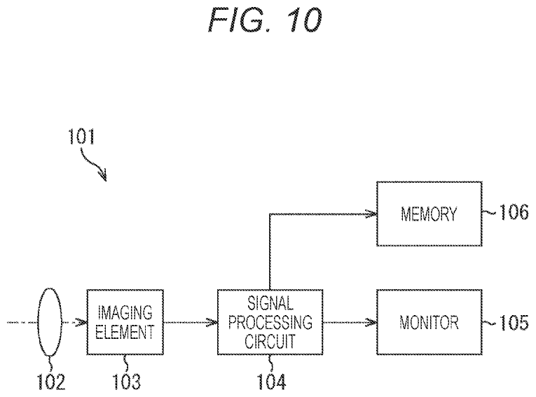

FIG. 10 is a block diagram illustrating a configuration example of an imaging device mounted on an electronic apparatus.

As illustrated in FIG. 10, an imaging device 101 includes an optical system 102, an imaging element 103, a signal processing circuit 104, a monitor 105, and a memory 106, and can capture a still image and a moving image.

The optical system 102 includes one or a plurality of lenses, guides image light (incident light) from a subject to the imaging element 103, and forms an image on a light-receiving surface (sensor unit) of the imaging element 103.

As the imaging element 103, the solid-state imaging element 12 described above is applied. Electrons are accumulated in the imaging element 103 for a certain period in accordance with the image formed on the light-receiving surface via the optical system 102. Then, a signal corresponding to the electrons accumulated in the imaging element 103 is supplied to the signal processing circuit 104.

The signal processing circuit 104 performs various types of signal processing on a pixel signal output from the imaging element 103. An image (image data) obtained by the signal processing applied by the signal processing circuit 104 is supplied to the monitor 105 to be displayed or supplied to the memory 106 to be stored (recorded) .

In the imaging device 101 configured as described above, by applying the above-described solid-state imaging element 12, for example, occurrence of a red-dot ghost phenomenon can be reliably eliminated, and an image with better image quality can be captured.

### Use Examples of Image Sensor

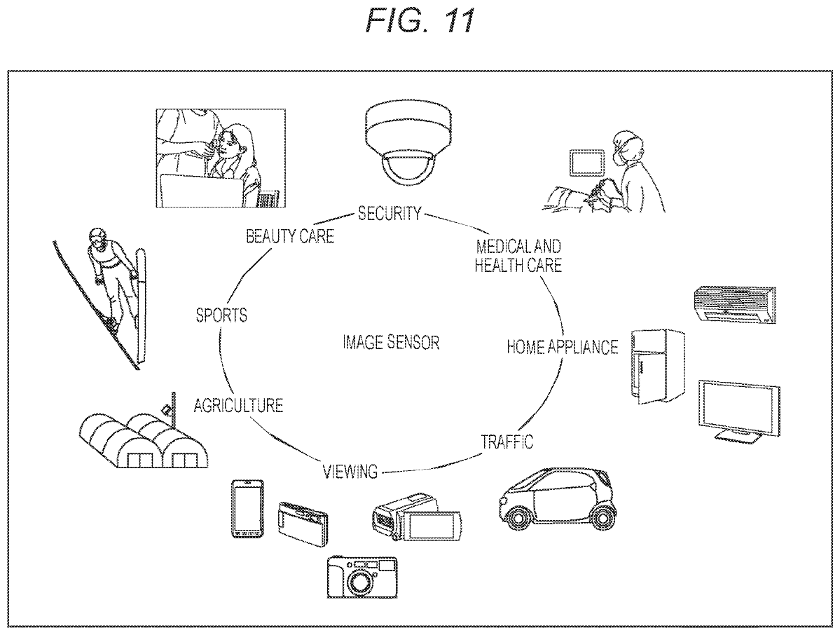

FIG. 11 is a diagram illustrating a use example of the above-mentioned image sensor (imaging element).

The image sensor described above can be used in various cases for sensing light such as visible light, infrared light, ultraviolet light, and X-ray as described below, for example.
A device that captures an image to be used for viewing, such as a digital camera and a portable device with a camera function.
A device for traffic purpose such as an in-vehicle sensor which takes images of the front, rear, surroundings, interior and the like of an automobile, a surveillance camera for monitoring traveling vehicles and roads, and a ranging sensor which measures a distance between vehicles and the like for safe driving such as automatic stop, recognition of a driver's condition and the like.
A device for home appliance such as a television, a refrigerator, and an air conditioner that takes an image of a user's gesture and performs a device operation according to the gesture
A device for medical and health care use such as an endoscope and a device that performs angiography by receiving infrared light
A device for security use such as a security monitoring camera and an individual authentication camera
A device for beauty care such as a skin measuring device that images skin and a microscope that images scalp
A device for sporting use such as an action camera and a wearable camera for sporting use and the like
A device for agricultural use such as a camera for monitoring land and crop states

### Combination Examples of Configurations

Note that the present technology can also have the following configuration.

### (1)

A solid-state imaging element including
a semiconductor substrate in which a photoelectric conversion element is provided for each pixel,
a filter layer stacked on a light-receiving surface side of the semiconductor substrate, and
a plasmon filter disposed in the filter layer of at least some red pixels of a plurality of the red pixels that receives light in a red wavelength region, the plasmon filter including a plasmon resonator having a predetermined periodic pattern.

### (2)

The solid-state imaging element according to (1),
in which, in the plasmon filter, a pitch of the pattern is corrected according to a position at which the red pixel is disposed.

### (3)

The solid-state imaging element according to (2),
in which the plasmon filter in the red pixel disposed at a central portion of the solid-state imaging element is configured in the pattern of a reference pitch that excites light in a red wavelength region, and
the plasmon filter in the red pixel disposed at a peripheral portion of the solid-state imaging element is configured in the pattern of a corrected pitch corrected to be wider than the reference pitch according to an angle at which light is obliquely incident on the red pixel.

### (4)

The solid-state imaging element according to any one of (1) to (3),
in which the plasmon filter has a hole-array structure in which a plurality of holes is provided in a metal thin film in the pattern.

### (5)

The solid-state imaging element according to any one of (1) to (4),
in which, for the red pixel, a two-layer structured filter including the plasmon filter and a color filter containing red dyestuff is disposed in the filter layer.

### (6)

The solid-state imaging element according to (5),
in which the plasmon filter is disposed closer to a light-incident side than the color filter is.

### (7)

The solid-state imaging element according to any one of (1) to (6),
in which a space between an on-chip lens stacked on the filter layer and an infrared cut filter stacked on a surface of a sealing glass that seals a sensor surface of the solid-state imaging element is filled with a material having a refractive index of 1 or more.

### (8)

The solid-state imaging element according to any one of (1) to (7),
in which an uneven surface in which recesses and projections are repeatedly arranged is provided on a boundary surface between a sealing glass that seals a sensor surface of the solid-state imaging element and an infrared cut filter stacked on a surface of the sealing glass.

### (9)

The solid-state imaging element according to (8),
in which a step in a thickness direction of the uneven surface is formed to be ¼ of a red wavelength.

### (10)

An electronic apparatus including a solid-state imaging element including
a semiconductor substrate in which a photoelectric conversion element is provided for each pixel,
a filter layer stacked on a light-receiving surface side of the semiconductor substrate, and
a plasmon filter disposed in the filter layer of at least some red pixels of a plurality of the red pixels that receives light in a red wavelength region, the plasmon filter including a plasmon resonator having a predetermined pattern.

Note that the present embodiment is not limited to the above-described embodiment, and various modifications can be made without departing from the gist of the present disclosure. Furthermore, the effects described in the present specification are merely examples and are not limited, and other effects may be provided.

### Reference Signs List

11 Imaging element package

12 Solid-state imaging element

13 Holding member

14 Sealing glass

15 Infrared cut filter

16 Imaging lens

21 Pixel

31 Wiring layer

32 Semiconductor substrate

33 Flattening film

34 Filter layer

35 On-chip lens

41 Photoelectric conversion unit

42 Color filter

43 Plasmon filter

51 Metal film

52 Hole

61 Filling material

1. A solid-state imaging element comprising:
a semiconductor substrate in which a photoelectric conversion element is provided for each pixel;
a filter layer stacked on a light-receiving surface side of the semiconductor substrate; and
a plasmon filter disposed in the filter layer of at least some red pixels of a plurality of the red pixels that receives light in a red wavelength region, the plasmon filter including a plasmon resonator having a predetermined periodic pattern.

2. The solid-state imaging element according to claim 1,
wherein, in the plasmon filter, a pitch of the pattern is corrected according to a position at which the red pixel is disposed.

3. The solid-state imaging element according to claim 2,
wherein the plasmon filter in the red pixel disposed at a central portion of the solid-state imaging element is configured in the pattern of a reference pitch that excites light in a red wavelength region, and
the plasmon filter in the red pixel disposed at a peripheral portion of the solid-state imaging element is configured in the pattern of a corrected pitch corrected to be wider than the reference pitch according to an angle at which light is obliquely incident on the red pixel.

4. The solid-state imaging element according to claim 1,
wherein the plasmon filter has a hole-array structure in which a plurality of holes is provided in a metal thin film in the pattern.

5. The solid-state imaging element according to claim 1,
wherein, for the red pixel, a two-layer structured filter including the plasmon filter and a color filter containing red dyestuff is disposed in the filter layer.

6. The solid-state imaging element according to claim 5,
wherein the plasmon filter is disposed closer to a light-incident side than the color filter is.

7. The solid-state imaging element according to claim 1,
wherein a space between an on-chip lens stacked on the filter layer and an infrared cut filter stacked on a surface of a sealing glass that seals a sensor surface of the solid-state imaging element is filled with a material having a refractive index of 1 or more.

8. The solid-state imaging element according to claim 1,
wherein an uneven surface in which recesses and projections are repeatedly arranged is provided on a boundary surface between a sealing glass that seals a sensor surface of the solid-state imaging element and an infrared cut filter stacked on a surface of the sealing glass.

9. The solid-state imaging element according to claim 8,
wherein a step in a thickness direction of the uneven surface is formed to be ¼of a red wavelength.

10. An electronic apparatus comprising a solid-state imaging element including
a semiconductor substrate in which a photoelectric conversion element is provided for each pixel,
a filter layer stacked on a light-receiving surface side of the semiconductor substrate, and
a plasmon filter disposed in the filter layer of at least some red pixels of a plurality of the red pixels that receives light in a red wavelength region, the plasmon filter including a plasmon resonator having a predetermined pattern.
